(19) United States
(12) Patent Application Publication
(10) Pub. No.: US 2012/0267228 A1
(43) Pub. Date: Oct. 25, 2012

(54) TOUCH PANEL

(75) Inventors: Yun Ki Hong, Gyunggi-do (KR); Hee Bum Lee, Gyunggi-do (KR); Kyoung Soo Chae, Gyunggi-do (KR); Seok Hyun Ji, Incheon (KR); Dong Sik Yoo, Seoul (KR); Byung Chul Lee, Seoul (KR); Sang Joon Nam, Gyunggi-do (KR)

(73) Assignees: Core River Semiconductor Co., Ltd., Seoul (KR); SAMSUNG ELECTRO-MECHANICS CO., LTD., Gyunggi-do (KR)

(21) Appl. No.: 13/352,264

(22) Filed: Jan. 17, 2012

(30) Foreign Application Priority Data
Apr. 21, 2011 (KR) 1020110037487

(51) Int. Cl. H03K 17/975

(52) U.S. Cl. 200/600

(57) ABSTRACT

Disclosed herein is a capacitive type touch panel, including: a transparent substrate; and a transparent electrode formed on the transparent substrate, wherein the transparent electrode has first, second, and third patterns sequentially formed in either a short direction or a long direction of the transparent substrate. According to the present invention, the one-layer capacitive type touch panel according to the present invention can easily recognize the coordinates of touched points by the touch and accurately recognize the coordinates. Furthermore, the transparent electrode patterns according to the present invention allow realization of multi-touch and improvement in driving reliability.

### CROSS REFERENCE TO RELATED APPLICATION

This application claims the benefit of Korean Patent Application No. 10-2011-0037487, filed on Apr. 21, 2011, entitled “Capacitive Type Touch Panel”, which is hereby incorporated by reference in its entirety into this application.

### BACKGROUND OF THE INVENTION

1. Technical Field

The present invention relates to a capacitive type touch panel.

2. Description of the Related Art

As computers using digital techniques develop, computer assisted devices have also been developed together, and personal computers, portable transmission apparatus, other personal information processing apparatus, or the like perform text and graphic processes using various input devices, such as a keyboard or a mouse.

With the rapid advancement of an information-oriented society widening the use of computers more and more, the following problems come alight in that it is increasingly difficult to efficiently operate products using the keyboard and mouse as only being currently responsible only for the input device function. Thus, the demand for a device that is simple, has minimum malfunction, and has the capability to easily input information is increasing.

Furthermore, current techniques for input devices exceed the level of fulfilling general functions and thus are progressing towards techniques related to high reliability, durability, innovation, designing and manufacturing. To this end, a touch panel has been developed as an input device capable of inputting information such as text and graphics.

The touch panel is mounted on the display surface of an image display device such as an electronic organizer, a flat panel display including a liquid crystal display (LCD), a plasma display panel (PDP), an electroluminescence (El) element, or the like, or a cathode ray tube (CRT), so that a user selects desired information while viewing the image display device.

The touch panel is classifiable as a resistive type, a capacitive type, an electromagnetic type, a surface acoustic wave (SAW) type, and an infrared type. The type of touch panel selected is one that is adapted for an electronic product in consideration of not only signal amplification problems, resolution differences and the degree of difficulty of designing and manufacturing technology but also in light of optical characteristic, electrical properties, mechanical properties, resistance to the environment, input properties, durability and economic benefits of the touch panel. In particular, a capacitive type touch panel is prevalently used in a broad range of fields currently.

In the prior art, as shown in FIG. 1, transparent electrode patterns of a single layer capacitive type touch panel includes first patterns 110 and second patterns 120, shapes thereof are generally rectangular. However, in the case of a rectangular pattern, since a reference area between respective channels is small when touching a specific area, there may be generated an area where coordinate calculation using magnitude of signal of the corresponding channel is not easy. In addition, there may be generated an area where coordinate calculation for each point is not easy, even at the time of multi-touch input, thereby deteriorating the reliability in operation of the multi-touch. In order to solve these problems, a tooth pattern constituted of a first pattern 210 and a second pattern 220, for example, a transparent electrode pattern as shown in FIG. 2, is proposed. This technique can improve the accuracy of coordinates and improve the recognition of coordinates with respect to touch points, but, when the multi-touch occurs along an advancing direction of a first pattern 210 or a second pattern 220, only one of the patterns can be recognized, and thus, operation in the multi-touch is not easily performed due to difficulty in recognition of multi-channels.

### SUMMARY OF THE INVENTION

The present invention has been made in an effort to provide a capacitive type touch panel capable of improving the accuracy in recognition of touched coordinates and the multi-touch operating performance, by allowing a plurality of channels in the touched area to sense touch and generate signals.

According to a preferred embodiment of the present invention, there is provided a capacitive type touch panel, including: a transparent substrate; and a transparent electrode formed on the transparent substrate, wherein the transparent electrode has first, second, and third patterns sequentially formed in either a short direction or a long direction of the transparent substrate, the first pattern consisting of a plurality of first protruding parts each having a width gradually narrowed from one end toward the other end of the transparent substrate, the second pattern consisting of a plurality of second protruding parts including first protrusions each formed toward one end of the transparent substrate correspondingly to a gap between the first protruding parts of the first pattern and second protrusions each having a width gradually narrowed toward the other end of the transparent substrate; and the third pattern consisting of a plurality of third protruding parts each formed from the other end toward one end of the transparent substrate correspondingly to a gap between the second protrusions of the second pattern.

According to another preferred embodiment of the present invention, there is provided a capacitive type touch panel, including: a transparent substrate; and a transparent electrode formed on the transparent substrate, wherein the transparent electrode has first, second, third, and fourth patterns sequentially formed in either a short direction or a long direction of the transparent substrate, the first pattern consisting of a plurality of first protruding parts each having a width gradually narrowed from one end toward the other end of the transparent substrate, the second pattern consisting of a plurality of second protruding parts including first protrusions each formed toward one end of the transparent substrate correspondingly to a gap between the first protruding parts of the first pattern and second protrusions each having a width gradually narrowed toward the other end of the transparent substrate, the third pattern consisting of a plurality of third protruding parts including first protrusions each formed toward one end of the transparent substrate correspondingly to a gap between the second protrusions of the second pattern and second protrusions each having a width gradually narrowed toward the other end of the transparent substrate, and the fourth pattern consisting of a plurality of fourth protruding parts each formed from the other end toward one end of the transparent substrate correspondingly to a gap between the second protrusions of the third pattern.

The transparent electrode may be formed of conductive polymer.

The conductive polymer may include poly-3, 4-ethylenedioxythiophene (PEDOT), polyaniline, polyacetylene, or polyphenylenevinylene.

The first protruding parts of the first pattern, which have widths in a protruding direction thereof, may be spaced from each other at a gap of from at least 1 mm to at most 8 mm.

The plurality of second protruding parts of the second pattern, which have widths in a protruding direction thereof, may be spaced from each other at a gap of from at least 1 mm to at most 8 mm.

The plurality of third protruding parts of the third pattern, which have widths in a protruding direction thereof, may be spaced from each other at a gap of from at least 1 mm to at most 8 mm.

The plurality of fourth protruding parts of the fourth pattern, which have widths in a protruding direction thereof, may be spaced from each other at a gap of from at least 1 mm to at most 8 mm.

### BRIEF DESCRIPTION OF THE DRAWINGS

FIG. 1 shows a pattern structure of a rectangular transparent electrode of a capacitive type touch panel according to the prior art;

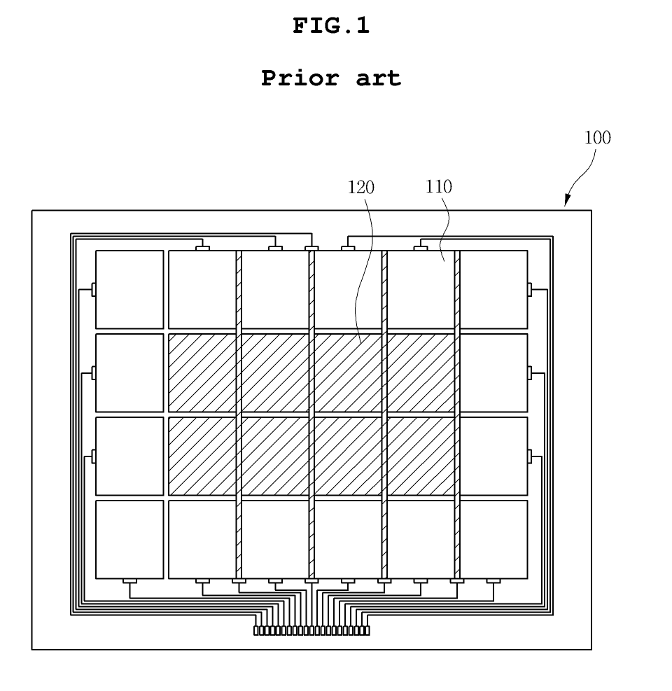

FIG. 2 shows a pattern structure of a tooth type transparent electrode of a capacitive type touch panel according to the prior art;

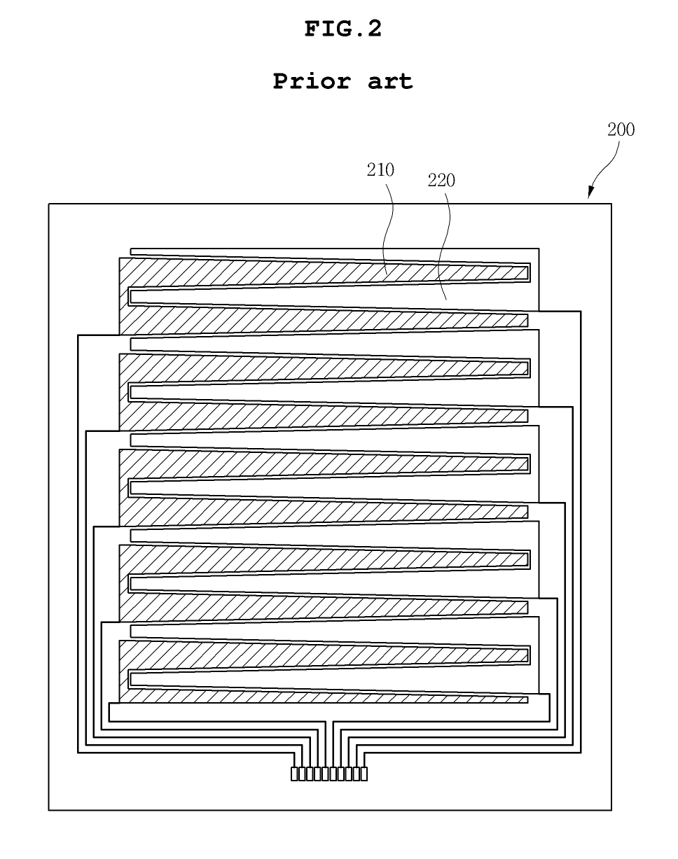

FIG. 3 shows a pattern structure of a transparent electrode of a capacitive type touch panel according to a first preferred embodiment of the present invention; and

FIG. 4 shows a pattern structure of a transparent electrode of a capacitive type touch panel according to a second preferred embodiment of the present invention.

### DESCRIPTION OF THE PREFERRED EMBODIMENTS

Various objects, advantages and features of the invention will become apparent from the following description of the embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In the description, the terms “first”, “second”, and so on are used to distinguish one element from another element, and the elements are not defined by the above terms. As used herein, the term “channel” means each portion where electrode wiring for electric connection of transparent electrode patterns is formed, and the term “a plurality of channels” means that a plurality of unit patterns of the transparent electrode are electrically connected by the electrode wiring. Further, in describing the present invention, a detailed description of related known functions or configurations will be omitted so as not to obscure the subject of the present invention.

Hereinafter, preferred embodiments of the present invention will be described in detail with reference to the accompanying drawings.

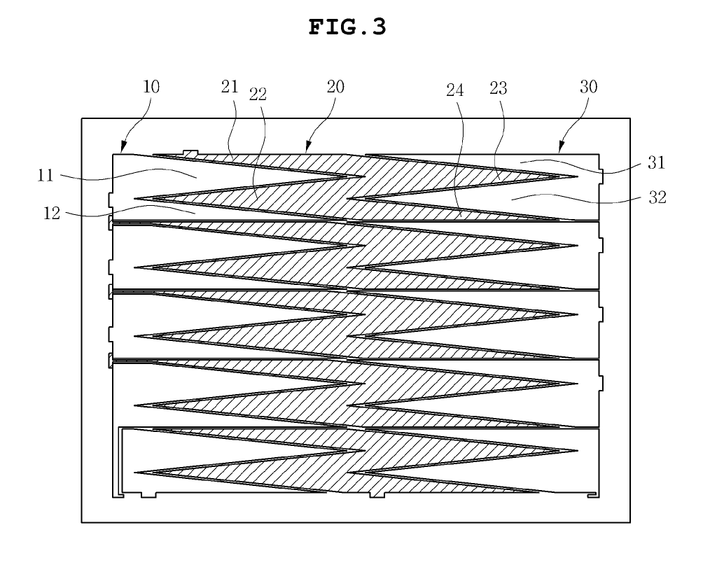

FIG. 3 shows a pattern structure of a transparent electrode of a capacitive type touch panel according to a first preferred embodiment of the present invention. According to a capacitive type touch panel according to a first preferred embodiment of the present invention, includes: a transparent substrate 1; and a transparent electrode formed on the transparent substrate 1. The transparent electrode has a first pattern 10, a second pattern 20, and a third pattern 30 sequentially formed in either a short direction or a long direction of the transparent substrate 1. The first pattern 10 consists of a plurality of first protruding parts 11 and 12 each having a width gradually narrowed from one end toward the other end of the transparent substrate 1. The second pattern 20 consists of a plurality of second protruding parts including first protrusions 21 and 22 each formed toward one end of the transparent substrate correspondingly to a gap between the first protruding parts 11 and 12 of the first pattern 10 and second protrusions 23 and 24 each having a width gradually narrowed toward the other end of the transparent substrate 11. The third pattern 30 consists of a plurality of third protruding parts 31 and 32 each formed from the other end toward one end of the transparent substrate 1 correspondingly to a gap between the second protrusions 23 and 24 of the second pattern 20.

As the transparent substrate 1, any materials that retain above a predetermined hardness may be used without particular limitation. Example thereof may include polyethyleneterephtalate (PET), polycarbonate (PC), polymethylmethacrylate (PMMA), polyethylenenaphthalate (PEN), polystyrene (PS), biaxially oriented polystyrene (K-resin containing biaxially oriented PC, BOPS), glass or reinforced glass and the like. In addition, since the transparent electrode is formed on one surface of the transparent substrate 1, a surface treatment layer may be formed on one surface of the transparent substrate 1 by performing a high frequency treatment, a primer treatment or the like thereon, in order to improve adhesion between the transparent substrate 1 and the transparent electrode.

The transparent electrode, which serves to generate signals when a touch panel is touched to by a user to allow a controller (not shown) to recognize coordinates thereof, is formed on one surface of the transparent substrate 1. The transparent electrode may be formed of ITO or a conductive polymer. Here, examples of the conductive polymer may include poly-3, 4-ethylenedioxythiophene (PEDOT), polyaniline, polyacetylene, polyphenylenevinylene, or the like, but are not limited thereto. The present invention is directed to a pattern structure of a one-layer transparent electrode, which will be described in detail as follows.

The transparent electrode of the capacitive type touch panel according to a first preferred embodiment of the present invention includes the first pattern 10, the second pattern 20, and the third pattern 30. The first pattern 10, the second pattern 20, and the third pattern 30 of the transparent electrode are sequentially formed from one end of the transparent substrate 1.

The first pattern 10 is formed from one end toward the other end of the transparent substrate 1, and has a plurality of first protruding parts 11 and 12 each having a width gradually narrowed. Each of the first protruding parts 11 and 12 has a width gradually narrowed, and may have an equilateral triangle shape where one lateral end of the transparent substrate is used as a bottom side. However, the shape of the first protruding part is limited to this shape, and any shape of which a width is gradually narrowed may be used for the pattern of the first protruding part. A formation gap between the protruding parts 11 and 12 may be regulated or changed depending on the touched area by the touch unit. If a standard size of the area generally touched is ø8 mm, the formation gap between the first protruding parts 11 and 12 may be in the range of from at least 1 mm to at most 8 mm. Therefore, at least two patterns of the transparent electrode are sensed on the touched area, thereby improving easiness and accuracy in calculating coordinate values.

The second pattern 20 consists of a plurality of second protruding parts including first protrusions 21 and 22 and second protrusions 23 and 24. Each of the first protrusions 21 and 22 is formed correspondingly to the first protruding parts 11 and 12 of the first pattern 10 and has a width gradually narrowed in a direction of one end of the transparent substrate 1. Each of the second protrusions 23 and 24 has a width gradually narrowed in the counter direction, that is, in a direction of the other end of the transparent substrate 1. The second protrusions 23 and 24 have similar shapes to the first protruding parts 11 and 12. As such, the first protruding parts 11 and 12 and the first protrusions 21 and 22 of the second protruding parts are formed correspondingly to each other, and thus, with respect to a predetermined touched area, the first pattern 10 and the second pattern 20 are simultaneously touched, thereby accurately calculating the coordinate values of the touched area through respective channels. The first protruding parts 11 and 12, and the second protrusions 21 and 22 of the second pattern 20 corresponding to the first protruding parts 11 and 12 are formed to have a complementary space between each other. That is, the first pattern 10 and the second pattern 20 are formed within the minimum area where they can be present together with each other. Therefore, both of the first pattern 10 and the second pattern 20 may be designed to be touched on the minimum area touched by a touch unit of a general capacitive type touch panel. Since the area touched by the touch unit has a size of approximately ø8 mm, the formation gap between the plurality of second protruding parts may be specifically in the range of from at least 1 mm to at most 8 mm. As such, the widths of the first protruding parts 11 and 12 are gradually narrowed and the widths of the first protrusions 21 and 22 of the second protruding parts are gradually widened correspondingly to the first protruding parts 11 and 12, and thus, channels on the touched area is sensed by the first pattern 10 and the second pattern, thereby improving the accuracy in recognition of the touched coordinate area. The formation gap between the protruding parts is not limited thereto, and the formation gap between the first protruding parts 11 and 12 and the formation gap between the second protruding parts can be regulated according to the change of the touched area by the touch unit. Accordingly, the number of channels sensed at the time of touch is increased by regulating the widths of the protruding parts, thereby accurately calculating coordinate values of the touched points and facilitating to recognize multi-touch. In addition, the same effects can be obtained by forming each of the plurality of first protruding parts 11 and 12 of the first pattern 10 in a range of from at least 1 mm to at most 8 mm. As a result, if a plurality of unit patterns each constituting the first pattern 10 and the second pattern 20 are formed to provide more channels, accuracy in coordinate calculation with respect to touch recognition and reliability in recognition of multi-touch can be improved and secured.

The third pattern 30 consists of a plurality of third protruding parts 31 and 32, which are formed from the other end toward one end of the transparent substrate 1, correspondingly to the second protrusions 23 and 24 of the second pattern 20. Also in the third pattern 30, the third protruding parts 31 and 32 correspond to the second protrusions 23 and 24 of the second pattern 20. Here, the width of each of the plurality of second protrusions 23 and 24 of the second pattern 20 is gradually narrowed, and each of the third protruding parts 31 and 32 may be formed to have a width of which the size corresponds to a gap between the second protrusions 23 and 24 of the second pattern 20. Also in this case, the second protrusions 23 and 24 of the second protruding parts, and the third protruding parts 31 and 32 are formed to have a complementary space between each other, like the first pattern 10 and the second pattern 20. That is, the second pattern 20 and the third pattern 30 may be formed within the minimum area where they can be present together with each other, based on the specific area Therefore, like the first pattern 10 and the second pattern 20 as described above, by forming the second protrusions 23 and 24 of the second pattern 20 and the third protruding parts 31 and 32 of the third pattern 30, as two kinds of patterns, to have a formation gap between the protrusions or the protruding parts, of from at least 1 mm to at most 8 mm, at least two patterns of the transparent electrode can sense signals on the touched area of ø8 mm which is touched at the time of general touch, thereby improving easiness in coordinate calculation and performance in recognition of multi-touch. Other details will be omitted since they overlap with the features with respect to the first pattern 10 and the second pattern 20.

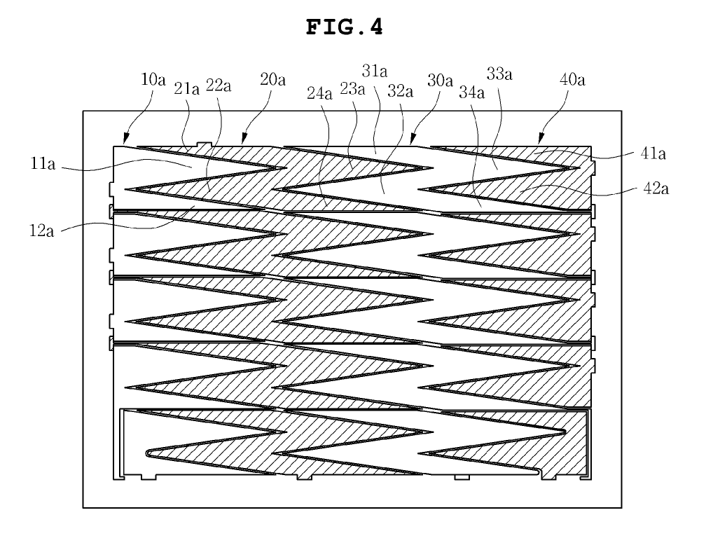

FIG. 4 shows a pattern structure of a transparent electrode of a capacitive type touch panel according to a second preferred embodiment of the present invention. According to a capacitive type touch panel according to a second preferred embodiment of the present invention, includes: a transparent substrate 2; and a transparent electrode formed on the transparent substrate 2. The transparent electrode has a first pattern 10a, a second pattern 20a, a third pattern 30a, and a fourth pattern 40a, sequentially formed in either a short direction or a long direction of the transparent substrate 2. The first electrode pattern 10a consists of a plurality of first protruding parts 11a and 12a each having a width gradually narrowed from one end toward the other end of the transparent substrate 2. The second electrode pattern 20a consists of a plurality of second protruding parts 21a, 22a, 23a, and 24a including first protrusions 21a and 22a each formed toward one end of the transparent substrate correspondingly to a gap between the first protruding parts 11a and 12a of the first pattern 10a and second protrusions 23a and 24a each having a width gradually narrowed toward the other end of the transparent substrate 2. The third electrode pattern 30a consists of a plurality of third protruding parts 31a, 32a, 33a, and 34a including first protrusions 31a and 32a each formed toward one end of the transparent substrate correspondingly to a gap between the second protrusions 23a and 24a of the second pattern 20a and second protrusions 33a and 34a each having a width gradually narrowed toward the other end of the transparent substrate 2. The fourth pattern 40a consists of a plurality of fourth protruding parts 41a and 42a each formed from the other end toward one end of the transparent substrate 2 correspondingly to a gap between the second protrusions 33a and 34a of the third pattern 30a.

Hereinafter, the description overlapping with the capacitive type touch panel according to the first preferred embodiment of the present invention will be omitted.

The first pattern 10a is formed from one end toward the other end of the transparent substrate 2, and has a plurality of first protruding parts 11a and 12a each having a width gradually narrowed. Each of the first protruding parts 11a and 12a has a width gradually narrowed, and may have an equilateral triangle shape where one lateral end of the transparent substrate 2 is used as a bottom side. However, the shape of the first protruding part is limited to this shape, and any shape of which a width is gradually narrowed may be used for the pattern of the first protruding part. The formation width of each of the first protruding parts 11a and 12a may be regulated or changed depending on the touched area by the touch unit. If the standard size of the area generally touched is ø8 mm, the formation gap between the first protruding parts 11a and 12a may be in the range of from at least 1 mm to at most 8 mm. As such, since at least two patterns sense the touched area, and thus multi-touch panels can be realized and driving reliability can be improved.

The second pattern 20a consists of a plurality of second protruding parts including first protrusions 21a and 22a and second protrusions 23a and 24a. Each of the first protrusions 21a and 22a is formed correspondingly to the first protruding parts 11a and 12a of the first pattern 10a and has a width gradually narrowed in a direction of one end of the transparent substrate 2. Each of the second protrusions 23a and 24a has a width gradually narrowed in the counter direction, that is, in a direction of the other end of the transparent substrate 2. The second protrusions 23a and 24a of the second protruding parts have similar shapes to the first protruding parts 11a and 12a. The first protruding parts 11a and 12a and the first protrusions 21a and 22a of the second protruding parts are formed correspondingly to each other, and thus, the first pattern 10a and the second pattern 20a are simultaneously touched with respect to a predetermined touched area, thereby accurately calculating the coordinate values of the touched area through respective channels. The first protruding parts 11a and 12a, and the second protrusions 21a and 22a of the second protruding parts corresponding to the first protruding parts 11a and 12a are formed to have a complementary space between each other. That is, the first pattern 10a and the second pattern 20a are formed within the minimum area where they can be present together with each other. Specifically, if the size of the area touched by the touch unit generally corresponds to an area size of ø8 mm, the second protruding parts of the second pattern 20a or the first protruding parts 11a and 12a can be formed to have a formation gap of from at least 1 mm to at most 8 mm, respectively. The sizes of the formation gaps between the first protruding parts 11a and 12a and between the second protruding parts are not limited thereto, and may be changed and regulated according to the size of the area touched by the touch unit. Other details will be omitted herein since they overlap with the features with respect to the second pattern 20a.

The third electrode pattern 30a consists of a plurality of third protruding parts including first protrusions 31a and 32a each formed toward one end of the transparent substrate 2 correspondingly to a gap between the second protrusions 23a and 24a of the second pattern 20a and second protrusions 33a and 34a each having a width gradually narrowed toward the other end of the transparent substrate 2. When the first protrusions 31a and 32a of the third protruding parts are formed correspondingly to the second protrusions 23a and 24a of the second protruding parts, the second pattern 20a and the third pattern 30a may be formed to be simultaneously sensed within a touch area of at most ø8 mm. As such, the second protrusions 23a and 24a of the second pattern 20a and the first protrusions 31a and 32a of the third pattern 30a are formed correspondingly to each other, and thus, the second pattern 20a and the third pattern 30a can be correspondingly formed in a complementary shape therebetween. As such, the second pattern 20a and the third pattern 30a can be correspondingly formed in a complementary shape, and thus, the second protrusions 23a and 24a of the second pattern 20a and the first protrusions 31a and 32a of the first pattern 30a are simultaneously touched at the time of touching a specific area, thereby accurately calculating the coordinate values and recognizing more accurate touch coordinates. In addition, while the second pattern 20a and the third pattern 30a are sequentially formed, by designing the patterns such that the pattern width of the transparent electrode is changed along a sequential direction in which the second pattern 20a and the third pattern 30a are formed, the degree of multi-touch recognition according to the direction in which the patterns are formed can be further increased. Each gap between the third protruding parts of the third pattern 30a may be formed in a range of 1 to ø8 mm. As such, the first protrusions 21a and 22a of the second pattern 20a are formed correspondingly to a gap between the second protrusions 33a and 34b of the third pattern 30a, and thus, the two patterns can be simultaneously sensed and recognized on the touched area in a range of 1 to ø8 mm. The gap between the third protruding parts is not limited thereto, and the protruding parts of the pattern can be variously formed only if at least two patterns are sensed and recognized in a specific area.

The fourth pattern 40a consists of a plurality of fourth protruding parts 41a and 42a each formed from the other end toward one end of the transparent substrate 2 correspondingly to a gap between the second protrusions 33a and 34a of the third pattern 30a. Also in the fourth pattern 40a, the fourth protruding parts 41a and 42a are formed to have shapes complementary to the second protrusions 33a and 34a of the third pattern 30a. Therefore, coordinate values at two channels of the third pattern 30a and the fourth pattern 40a can be calculated at the time of touch in a specific area, thereby enabling more accurate coordinate recognition and more easy multi-touch recognition. In a case where the second protrusions 33a and 34a of the third pattern 30a and the fourth protruding parts 41a and 42a are formed correspondingly to each other, when the two protruding parts are formed complementarily, the formation gap between the two protruding parts having widths in a protruding direction may be in a range of from at least 1 mm to at most 8 mm. The above range is given, supposing that the area touched in a general capacitive type touch panel is ø8 mm, and thus, the second protrusions 33a and 34a of the third pattern 30a and the fourth protruding parts 41a and 42a of the fourth pattern 40a need not be formed within the above range. The patterns can be formed in various ranges of gaps depending on the kind and use of the touch unit.

As set forth above, the one-layer capacitive type touch panel according to the present invention can easily recognize the coordinates of touched points by the touch and accurately recognize the coordinates.

Furthermore, the transparent electrode patterns according to the present invention allow realization of multi-touch and improvement in driving reliability.

Although the preferred embodiments of the present invention have been disclosed for illustrative purposes, they are for specifically explaining the present invention and thus the capacitive type touch panel according to the present invention is not limited thereto, but those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A capacitive type touch panel, comprising:
a transparent substrate; and
a transparent electrode formed on the transparent substrate,
wherein the transparent electrode has first, second, and third patterns sequentially formed in either a short direction or a long direction of the transparent substrate,
the first pattern consisting of a plurality of first protruding parts each having a width gradually narrowed from one end toward the other end of the transparent substrate,
the second pattern consisting of a plurality of second protruding parts including first protrusions each formed toward one end of the transparent substrate correspondingly to a gap between the first protruding parts of the first pattern and second protrusions each having a width gradually narrowed toward the other end of the transparent substrate, and
the third pattern consisting of a plurality of third protruding parts each formed from the other end toward one end of the transparent substrate correspondingly to a gap between the second protrusions of the second pattern.

2. A capacitive type touch panel, comprising:
a transparent substrate; and
a transparent electrode formed on the transparent substrate,
wherein the transparent electrode has first, second, third, and fourth patterns sequentially formed in either a short direction or a long direction of the transparent substrate,
the first pattern consisting of a plurality of first protruding parts each having a width gradually narrowed from one end toward the other end of the transparent substrate,
the second pattern consisting of a plurality of second protruding parts including first protrusions each formed toward one end of the transparent substrate correspondingly to a gap between the first protruding parts of the first pattern and second protrusions each having a width gradually narrowed toward the other end of the transparent substrate,
the third pattern consisting of a plurality of third protruding parts including first protrusions each formed toward one end of the transparent substrate correspondingly to a gap between the second protrusions of the second pattern and second protrusions each having a width gradually narrowed toward the other end of the transparent substrate, and
the fourth pattern consisting of a plurality of fourth protruding parts each formed from the other end toward one end of the transparent substrate correspondingly to a gap between the second protrusions of the third pattern.

3. The capacitive type touch panel as set forth in claim 1, wherein the transparent electrode is formed of conductive polymer.

4. The capacitive type touch panel as set forth in claim 3, wherein the conductive polymer includes poly-3, 4-ethylenedioxythiophene (PEDOT), polyaniline, polyacetylene, or polyphenylenevinylene.

5. The capacitive type touch panel as set forth in claim 2, wherein the first protruding parts of the first pattern, which have widths in a protruding direction thereof, are spaced from each other at a gap of from at least 1 mm to at most 8 mm.

6. The capacitive type touch panel as set forth in claim 2, wherein the plurality of second protruding parts of the second pattern, which have widths in a protruding direction thereof, are spaced from each other at a gap of from at least 1 mm to at most 8 mm.

7. The capacitive type touch panel as set forth in claim 2, wherein the plurality of third protruding parts of the third pattern, which have widths in a protruding direction thereof, are spaced from each other at a gap of from at least 1 mm to at most 8 mm.

8. The capacitive type touch panel as set forth in claim 2, wherein the plurality of fourth protruding parts of the fourth pattern, which have widths in a protruding direction thereof, are spaced from each other at a gap of from at least 1 mm to at most 8 mm.
